(19) United States
(12) Patent Application Publication
(10) Pub. No.: US 2024/0206232 A1
(43) Pub. Date: Jun. 20, 2024

(54) ORGANIC LIGHT EMITTING DISPLAY PANEL, MANUFACTURING METHOD THEREFOR AND DISPLAY DEVICE

(71) Applicants: BOE Technology Group Co., Ltd., Beijing (CN); Hefei Xinsheng Optoelectronics Technology Co., Ltd., Hefei, Anhui (CN)

(72) Inventors: Gu YAO, Beijing (CN); Yu WANG, Beijing (CN); Xiao FU, Beijing (CN)

(21) Appl. No.: 17/797,820

(22) PCT Filed: Oct. 22, 2021
(86) PCT No.: PCT/CN2021/125542

§ 371 Date: Aug. 5, 2022

(30) Foreign Application Priority Data
Feb. 22, 2021 (CN) 202110197561.5

(51) Int. Cl. H10K 59/122; H10K 59/12; H10K 59/80

(52) U.S. Cl. CPC H10K 59/122; H10K 59/1201; H10K 59/80522

(57) ABSTRACT

The display panel includes a planarization layer; an auxiliary electrode in a non-light emitting region, where orthographic projections of at least part of the auxiliary electrode and the planarization layer on the substrate do not overlap; a first electrode; a pixel defining layer having a pixel opening region from which the first electrode is exposed and a first through hole from which the auxiliary electrode is exposed; an organic light emitting layer covering part of the pixel defining layer, and orthographic projections of the organic light emitting layer and the auxiliary electrode on the substrate do not overlap; a lap joint electrode in the first through hole; and a second electrode being of a whole-layer structure, and being coupled to the auxiliary electrode through the lap joint electrode.

### CROSS REFERENCE TO RELATED APPLICATION

The present application is a national phase entry under 35 U.S.C. § 371 of International Application No. PCT/CN2021/125542, filed on Oct. 22, 2021, which claims the priority to Chinese Patent Application No. 202110197561.5, filed with the China National Intellectual Property Administration on Feb. 22, 2021 and entitled “Organic Light Emitting Display Panel, Manufacturing Method therefor and Display Device”, the entire contents of which are incorporated herein by reference.

### FIELD

The present disclosure relates to the technical field of display, and in particular to an organic light emitting display panel, a manufacturing method therefor and a display device.

### BACKGROUND

Compared with a liquid crystal display (LCD), an organic light emitting diode (OLED) has the advantages of self-emission, wide viewing angle, light weight etc., thereby being considered to be the next generation display technology.

An existing OLED device generally includes a first electrode, a second electrode, and a light emitting layer located between the first electrode and the second electrode. Depending on different light emergence directions, the OLED device may be divided into a bottom emission device and a top emission device. Owing to a larger aperture ratio and remarkable increase in the screen brightness, the top emission device has become a research focus in recent years.

The inventor has found the following problems in the prior art: a pixel defining structure generally defines a pixel unit, the first electrode on a substrate is separated by the pixel defining structure, the light emitting layer and the second electrode are both of a whole-layer structure, the top emission OLED device requires a second ultrathin electrode and a first reflective electrode to increase transmittance of light, but the second ultrathin transparent electrode results in a higher resistance and a dramatic IR drop.

### SUMMARY

Embodiments of the present disclosure provide an organic light emitting display panel, including:
a substrate with a light emitting region and a non-light emitting region;
a planarization layer on one side of the substrate;
an auxiliary electrode on the one side of the substrate same as the planarization layer and in the non-light emitting region, where an orthographic projection of at least part of the auxiliary electrode on the substrate and an orthographic projection of the planarization layer on the substrate do not overlap;
a first electrode on a side of the planarization layer away from the substrate;
a pixel defining layer on a side of the first electrode away from the substrate, where the pixel defining layer is provided with a pixel opening region from which the first electrode is exposed and a first through hole from which the auxiliary electrode is exposed;
an organic light emitting layer on the side of the first electrode away from the substrate, where the organic light emitting layer covers part of the pixel defining layer, and an orthographic projection of the organic light emitting layer on the substrate and an orthographic projection of the auxiliary electrode on the substrate do not overlap;
a lap joint electrode in the first through hole; and
a second electrode on a side of the organic light emitting layer away from the substrate, where the second electrode is of a whole-layer structure, and the second electrode is coupled to the auxiliary electrode through the lap joint electrode.

Optionally, in the organic light emitting display panel provided in the embodiments of the present disclosure, the planarization layer is provided with a first via hole, and the auxiliary electrode is in the first via hole.

Optionally, in the organic light emitting display panel provided in the embodiments of the present disclosure, in a direction perpendicular to the substrate, the first via hole penetrates through the planarization layer, and a thickness of the auxiliary electrode is same as a thickness of the planarization layer.

Optionally, in the organic light emitting display panel provided in the embodiments of the present disclosure, the thickness of the auxiliary electrode is 100 nm-700 nm.

Optionally, in the organic light emitting display panel provided in the embodiments of the present disclosure, in a direction perpendicular to the substrate, a thickness of the lap joint electrode is same as a thickness of the pixel defining layer.

Optionally, in the organic light emitting display panel provided in the embodiments of the present disclosure, the thickness of the pixel defining layer is 100 nm-700 nm.

Optionally, in the organic light emitting display panel provided in the embodiments of the present disclosure, the first electrode is a reflective electrode, material of the second electrode is a transparent conductive material, and material of the auxiliary electrode is a metal.

Optionally, in the organic light emitting display panel provided in the embodiments of the present disclosure, the first electrode serves as an anode, and the second electrode serves as a cathode.

Accordingly, embodiments of the present disclosure further provide a manufacturing method for an organic light emitting display panel, including:
providing a substrate with a light emitting region and a non-light emitting region;
forming a planarization layer and an auxiliary electrode on a same side of the substrate, where the auxiliary electrode is in the non-light emitting region, and an orthographic projection of at least part of the auxiliary electrode on the substrate and an orthographic projection of the planarization layer on the substrate do not overlap;
forming a plurality of independent first electrodes on a side of the planarization layer away from the substrate;
forming a pixel defining layer on a side of the first electrodes away from the substrate, where the pixel defining layer is provided with pixel opening regions from which the first electrodes are exposed and a first through hole from which the auxiliary electrode is exposed;
forming an organic light emitting layer covering a whole surface on a side of the pixel defining layer away from the substrate;
shielding the organic light emitting layer with a mask, where the mask includes an opening region and a shielding region, the opening region corresponds to the auxiliary electrode, and the shielding region corresponds to other regions.

irradiating the opening region with laser, and removing a part of the organic light emitting layer corresponding to the opening region, such that the organic light emitting layer covers part of the pixel defining layer, and an orthographic projection of the organic light emitting layer on the substrate and an orthographic projection of the auxiliary electrode on the substrate do not overlap;
forming a lap joint electrode film layer on a side of the mask away from the substrate, where a part of the lap joint electrode film layer in the shielding region of the mask is disconnected from a part of the lap joint electrode film layer in the opening region;
removing the mask, where a lap joint electrode is formed in the part of the lap joint electrode film layer in the opening region; and
forming a second electrode covering a whole surface on a side of the organic light emitting layer away from the substrate, where the second electrode is coupled to the auxiliary electrode through the lap joint electrode.

Optionally, in the manufacturing method provided in the embodiments of the present disclosure, the forming a planarization layer and an auxiliary electrode on a same side of the substrate includes:
forming the planarization layer on the side of the substrate,
patterning the planarization layer to form a first via hole penetrating through the planarization layer, and
forming the auxiliary electrode in the first via hole.

Optionally, in the manufacturing method provided in the embodiments of the present disclosure, irradiation of the laser has a wavelength of 308-355 nm, an energy density of 10-6000 mJ/cm², a frequency of 100-3000 Hz, and time of 5-1000 ns.

Optionally, in the manufacturing method provided in the embodiments of the present disclosure, the forming an organic light emitting layer covering a whole surface on the side of the pixel defining layer away from the substrate includes:
forming the organic light emitting layer covering the whole surface on the side of the pixel defining layer away from the substrate in a vacuum evaporation or ink-jet printing manner.

Accordingly, embodiments of the present disclosure further provide a display device, including any one of the organic light emitting display panels mentioned above.

### BRIEF DESCRIPTION OF THE DRAWINGS

FIG. 1 is a structural schematic diagram of an organic light emitting display panel provided in an embodiment of the present disclosure;

FIG. 2 is a structural schematic diagram from a top view of an organic light emitting display panel provided in an embodiment of the present disclosure;

FIG. 3 is a flow chart of a manufacturing method for an organic light emitting display panel provided in an embodiment of the present disclosure;

FIG. 4A-FIG. 4I are structural schematic diagrams after respective steps being executed in a manufacturing method for an organic light emitting display panel provided in an embodiment of the present disclosure.

### DETAILED DESCRIPTION OF THE EMBODIMENTS

In order to make objectives, technical solutions and advantages of the present disclosure clearer, the following will describe embodiments of an organic light emitting display panel, a manufacturing method therefor and a display device provided in the present disclosure in detail with reference to accompanying drawings. It should be understood that the preferred embodiments described herein are merely illustrative of the present disclosure and are not intended to limit the present disclosure. The embodiments in the present application and the features in the embodiments may be mutually combined in the case of no conflicts.

A thickness, a size and a shape of each film layer in the accompanying drawings do not reflect a real ratio of the organic light emitting display panel, and only have an objective to illustrate the contents of the present disclosure.

### Embodiment 1

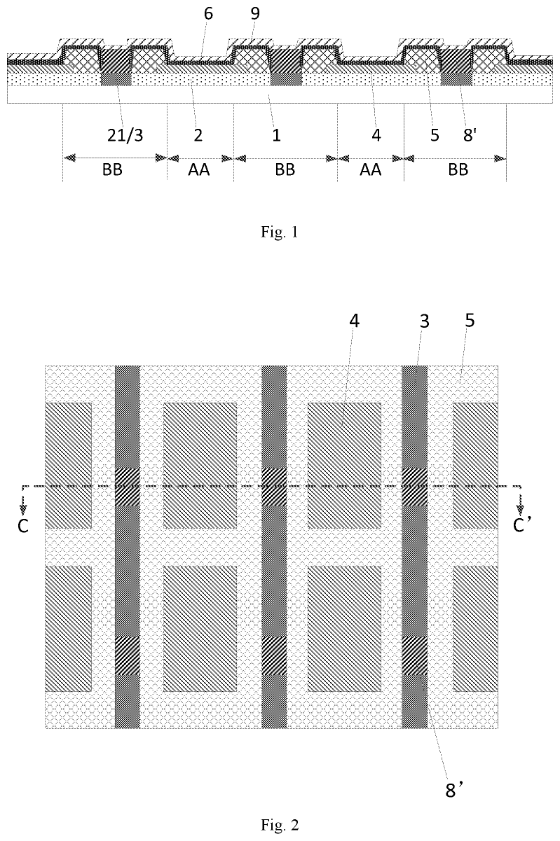

The embodiment of the present disclosure provides an organic light emitting display panel, as shown in FIG. 1 and FIG. 2. FIG. 1 is a schematic sectional diagram of the organic light emitting display panel, and FIG. 2 is a schematic diagram from a top view of part of film layers in FIG. 1. FIG. 1 is a schematic sectional diagram along a direction CC′ in FIG. 2.

The organic light emitting display panel includes:
a substrate 1 with a light emitting region AA and a non-light emitting region BB;
a planarization layer 2 located on one side of the substrate 1;
an auxiliary electrode 3 located on the same one side of the substrate 1 as the planarization layer 2 and located in the non-light emitting region BB, where an orthographic projection of at least part of the auxiliary electrode 3 on the substrate 1 and an orthographic projection of the planarization layer 2 on the substrate 1 do not overlap;
a first electrode 4 located on the side of the planarization layer 2 away from the substrate 1;
a pixel defining layer 5 located on the side of the first electrode 4 away from the substrate 1, where the pixel defining layer 5 has a pixel opening region 51 from which the first electrode 4 is exposed and a first through hole 52 from which the auxiliary electrode 3 is exposed;
an organic light emitting layer 6 located on the side of the first electrode 4 away from the substrate 1, where the organic light emitting layer 6 covers part of the pixel defining layer 5, and an orthographic projection of the organic light emitting layer 6 on the substrate and an orthographic projection of the auxiliary electrode 3 on the substrate 1 do not overlap;
a lap joint electrode 8′ located in the first through hole 52; and
a second electrode 9 located on the side of the organic light emitting layer 6 away from the substrate 1, where the second electrode 9 is of a whole-layer structure, and the second electrode 9 is coupled to the auxiliary electrode 3 by means of the lap joint electrode 8″.

It should be noted that in the case that the second electrode 9 is coupled to the auxiliary electrode 3 by means of the lap joint electrode 8′, the second electrode 9 is electrically connected to the lap joint electrode 8′, and the lap joint electrode 8′ is electrically connected to the auxiliary electrode 3, such that the second electrode 9 and the auxiliary electrode 3 are also in electrical communication, ie, coupling connection.

In FIG. 1 of Embodiment 1 of the present disclosure, an example in which the first electrode 4 (the anode) is below the organic light emitting layer 6 and the second electrode 9 (the cathode) is above the organic light emitting layer 6 is described. The solution in which the cathode and the anode are interchanged is similar to the embodiment of the present disclosure, which will not be repeated herein.

As shown in FIG. 1, since the thickness of the second electrode 9 is far smaller than that of the pixel defining layer 5, a mismatch gap between the second electrode 9 and the auxiliary electrode 3 is large, and poor electrical contact (false connection) between the second electrode 9 and the auxiliary electrode 3 is likely to be caused, therefore the lap joint electrode 8′ is formed in the first through hole 52 in the embodiment 1 of the present disclosure, and the lap joint electrode 8′ may remarkably reduce the mismatch gap, reduce the false connection between the second electrode 9) and the auxiliary electrode 3, and improve a yield of products.

The first electrode 4 (the anode) is of a patterned structure, such that the position in the substrate 1 containing the first electrode 4 (the anode) is a region of pixel units, and the position without the first electrode 4 (the anode) will not emit light and does not belong to a pixel unit even though covering the second electrode 9 (the cathode). For example, with reference to FIG. 1, the position without the first electrode 4 (the anode) is of a pixel defining region.

In specific implementations, in order not to increase a thickness of the organic light emitting display panel, in the organic light emitting display panel provided in the embodiments of the present disclosure, as shown in FIG. 1, the planarization layer 2 has a first via hole 21, and the auxiliary electrode 3 is located in the first via hole 21.

In specific implementations, in the organic light emitting display panel provided in the embodiments of the present disclosure, as shown in FIG. 1, in a direction perpendicular to the substrate 1, the first via hole 21 penetrates through the planarization layer 2, and the auxiliary electrode 3 has the same thickness as the planarization layer 2. Particularly, both the auxiliary electrode 3 and the planarization layer 2 may have a thickness of 100 nm-700 nm.

In specific implementations, in the organic light emitting display panel provided in the embodiments of the present disclosure, as shown in FIG. 1, in a direction perpendicular to the substrate 1, the lap joint electrode 8′ has the same thickness as the pixel defining layer 5. For example, both the lap joint electrode 8′ and the pixel defining layer 5 may have a thickness of 100 nm-700 nm. A material of the pixel defining layer 5 may be selected from resin, polyimide, organic silicon or silicon dioxide.

In specific implementations, in the organic light emitting display panel provided in the embodiments of the present disclosure, as shown in FIG. 1, the first electrode 4 (the anode) is a reflective electrode. The reflective electrode may be made of an alloy material, and the alloy material is obtained by mixing one or more of Al, Ag and Mg. The second electrode 9 (the cathode) is made of a transparent conductive material, and the cathode may be formed from a composite material of one or more of a magnesium-silver mixture, indium zinc oxide (IZO), indium tin oxide (ITO), aluminum doped zinc oxide (AZO), etc. The auxiliary electrode is made of a metal, and the material of the auxiliary electrode 3 may be selected from at least one of molybdenum, aluminum, copper, silver, and niobium.

It should be noted that in the accompanying drawings provided in the embodiments of the present disclosure, a size, a thickness, etc. of each film layer structure are merely schematic. In process implementations, a projection area of each film layer structure on the substrate may be the same or different. The projection area of each film layer structure as required may be achieved by means of an etching process. Moreover, the structure shown in the accompanying drawings does not define the geometric shape of each film layer structure, for example, the shape may be a rectangle shown in the accompanying drawings, or may be a trapezoid or other shapes formed by means of etching, and the structure may also be implemented by means of etching.

### Embodiment 2

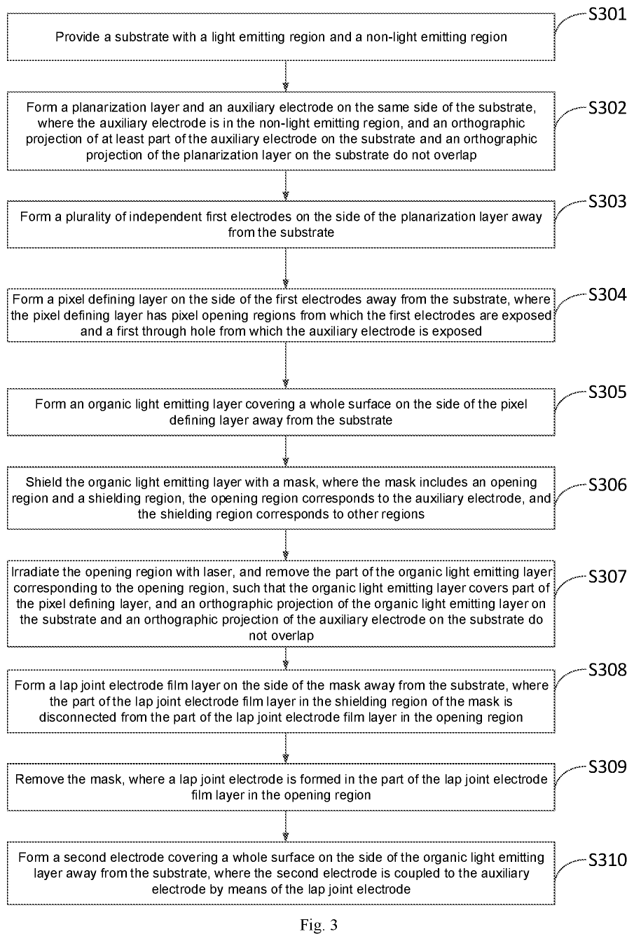

The embodiment of the present disclosure provides a manufacturing method for an organic light emitting display panel. As shown in FIG. 3, the method includes:
S301, provide a substrate which has a light emitting region and a non-light emitting region;
S302, form a planarization layer and an auxiliary electrode on the same side of the substrate, where the auxiliary electrode is located in the non-light emitting region, and an orthographic projection of at least part of the auxiliary electrode on the substrate and an orthographic projection of the planarization layer on the substrate do not overlap;
S303, form a plurality of independent first electrodes on the side of the planarization layer away from the substrate;
S304, form a pixel defining layer on the side of the first electrodes away from the substrate, where the pixel defining layer has pixel opening regions from which the first electrodes are exposed and a first through hole from which the auxiliary electrode is exposed;
‘S305, form an organic light emitting layer covering a whole surface on the side of the pixel defining layer away from the substrate;
S306, shield the organic light emitting layer with a mask, where the mask includes an opening region and a shielding region, the opening region corresponds to the auxiliary electrode, and the shielding region corresponds to other regions;
S307, irradiate the opening region with laser, and remove the part of the organic light emitting layer corresponding to the opening region, such that the organic light emitting layer covers part of the pixel defining layer, and an orthographic projection of the organic light emitting layer on the substrate and an orthographic projection of the auxiliary electrode on the substrate do not overlap;
S308, form a lap joint electrode film layer on the side of the mask facing away from the substrate, where the part of the lap joint electrode film layer located in the shielding region of the mask is disconnected from the part of the lap joint electrode film layer located in the opening region;
S309, remove the mask, where a lap joint electrode is formed in the part of the lap joint electrode film layer located in the opening region;
S310, form a second electrode covering a whole surface on the side of the organic light emitting layer away from the substrate, where the second electrode is coupled to the auxiliary electrode by means of the lap joint electrode.

According to the manufacturing method provided in the embodiments of the present disclosure, a part of the organic light emitting layer in a corresponding region is removed with laser irradiation, such that the organic light emitting layer covers part of the pixel defining layer, and an orthographic projection of the organic light emitting layer on the substrate and an orthographic projection of the auxiliary electrode on the substrate do not overlap. Then the formed second electrode is coupled to the auxiliary electrode by means of the lap joint electrode, and the second electrode and the auxiliary electrode are equivalently connected in parallel, such that the auxiliary electrode may reduce the resistance of the second electrode, thereby reducing the IR drop. In addition, according to the embodiments of the present disclosure, when the part of the organic light emitting layer in the corresponding region is removed with laser irradiation, the mask is used to shield the region not irradiated by the laser, such that the mask may effectively isolate particles generated during laser irradiation, thereby avoiding pollution of the particles generated during laser irradiation to the organic light emitting layer, and facilitating removal of the particles. Thus, the embodiments of the present disclosure achieve reduction to the resistance of the second electrode on the basis of not polluting the organic light emitting laver.

### Embodiment 3

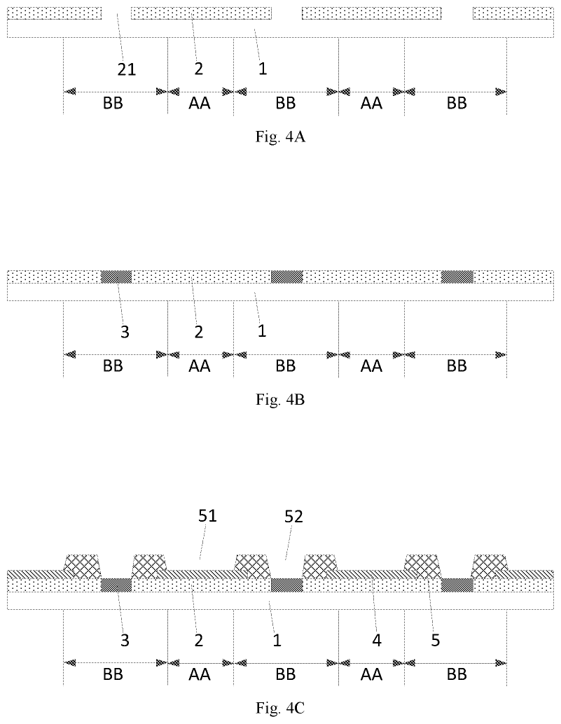

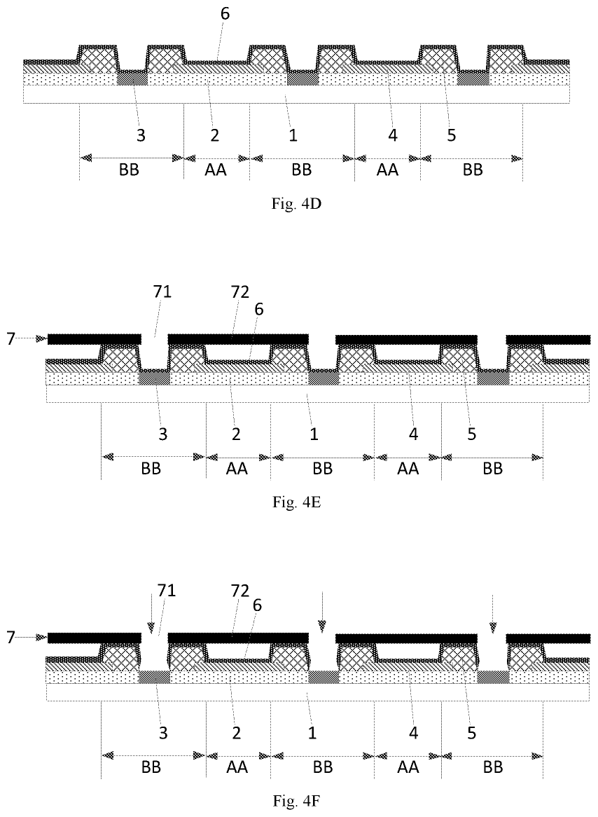

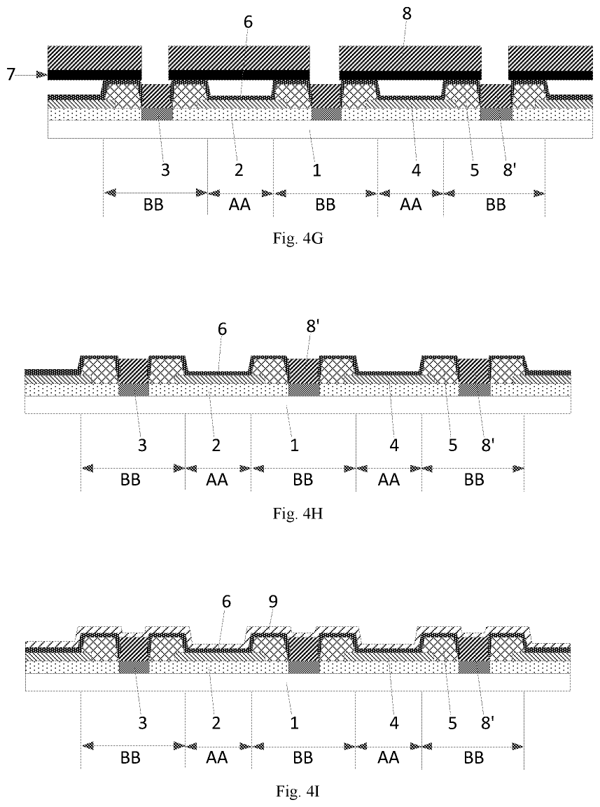

The embodiment of the present disclosure provides a manufacturing method for an organic light emitting display panel. As shown in FIG. 4A-FIG. 4I, the method includes the following manufacturing steps.
(1) A substrate 1 is provided. The substrate 1 has light emitting regions AA and non-light emitting regions BB. A planarization layer 2 is formed on the substrate 1. The part of the planarization layer 2 corresponding to the non-light emitting regions BB is patterned to form first via holes 21 penetrating through the planarization layer 2 as shown in FIG. 4A. For example, the planarization layer 2 may be patterned to form the first via holes 21 by using a process such as exposure and etching, and the planarization layer 2 may be made of resin etc.

The substrate 1 is a substrate on which a thin film transistor array is completed.
(2) Auxiliary electrodes 3 in the first via holes 21 are formed as shown in FIG. 4B. The auxiliary electrode 3 is made of a metal. The material of the auxiliary electrode 3 may be selected from at least one of molybdenum, aluminum, copper, silver and niobium. A specific size of the auxiliary electrode 3 is not limited herein. In a direction perpendicular to the substrate 1, the auxiliary electrode 3 may have the same thickness as or a different thickness from the planarization layer 2. For example, the auxiliary electrode 3 may have a thickness of 100 nm-700 nm.
(3) A plurality of independent first electrodes 4 and a pixel defining layer 5 on the side of the planarization layer 2 facing away from the substrate 1 are formed. The pixel defining layer 5 has pixel opening regions 51 from which the first electrodes 4 are exposed and first through holes 52 from which the auxiliary electrodes 3 are exposed as shown in FIG. 4C. In the embodiments of the present disclosure, an example in which the first electrodes 4 serve as an anode and a second electrode serves as a cathode is described, and the auxiliary electrode 3 serves as an auxiliary cathode. The solution in which the first electrodes 4 serve as a cathode and the second electrode serves as an anode is similar to the present disclosure, which will not be repeated herein. Moreover, the first electrodes 4 may be formed in a magnetron sputtering or a vacuum evaporation manner, and patterned by using processes such as exposure and etching. The first electrodes 4 are reflective electrodes. The reflective electrodes may be made of an alloy material, and the alloy material is obtained by mixing one or more of Al, Ag and Mg.

For example, the material of the pixel defining layer 5 may be selected from resin, polyimide, organic silicon or silicon dioxide, and in the direction perpendicular to the substrate 1, the pixel defining layer 5 may have a thickness of 100 nm-700 nm.
(4) An organic light emitting layer 6 covering a whole surface on the side of the pixel defining layer 5 away from the substrate 1 as shown in FIG. 4D is formed. The organic light emitting layer 6 may be formed in a vacuum evaporation or ink-jet printing manner. It should be noted that the organic light emitting layer 6 may be of a multi-layer structure, and according to the requirement of light emission, the organic light emitting layer 6 may include a hole injection layer (HIL), a hole transport layer (HTL), an emitting material layer (EML), an electron transport layer (ETL) and an electron injection layer (EIL).
(5) The organic light emitting layer 6 is shielded by a mask 7. The mask 7 includes opening regions 71 and shielding regions 72. The opening regions 71 correspond to the auxiliary electrodes 3, and the shielding regions 72 correspond to other regions, as shown in FIG. 4E.
(6) As shown in FIG. 4F, the opening regions 71 are irradiated by laser (shown by arrows), and the part of the organic light emitting layer 6 corresponding to the opening regions 71 are removed, such that the organic light emitting layer 6 covers part of the pixel defining layer 5, and an orthographic projection of the organic light emitting layer 6 on the substrate 1 and an orthographic projection of the auxiliary electrode 3 on the substrate 1 do not overlap. For example, laser irradiation has a wavelength of 308-355 nm, preferably, 330 nm, 308 nm, 355 nm, etc. The laser irradiation has an energy density of 10-6000 mJ/cm², a frequency of 100-3000 Hz. and time of 5-1000 ns.
(7) A lap joint electrode film layer 8 is formed on one side of the mask 7 away from the substrate 1. In a direction perpendicular to the substrate 1, the lap joint electrode film layer 8 may have the same thickness as the pixel defining layer 5. Since the pixel defining layer 5 has the first through holes 52 from which the auxiliary electrodes 3 are exposed, and the first through holes 52 correspond to the opening regions 71, the part of the lap joint electrode film layer 8 located in the shielding region 72 of the mask 7 is disconnected from the part of the lap joint electrode film layer 8 located in the opening region 71 as shown in FIG. 4G.
(8) The mask 7 is removed. The part of the lap joint electrode film layer 8 located in the shielding regions 72 of the mask 7 is removed together, and the part of the lap joint electrode film layer 8 located in the opening regions 71 is reserved to form lap joint electrodes 8′. The lap joint electrodes 8′ are located in the first through holes 52 as shown in FIG. 4H. For example, in the direction perpendicular to the substrate 1, the lap joint electrode 8′ has the same thickness as the pixel defining layer 5. In the step (6), particles will be generated when the organic light emitting layer 6 is irradiated with laser, although the mask 7 may isolate the particles, residual particles will exist on the auxiliary electrodes 3. The lap joint electrodes 8′ may play a wrapping role on the residual particles, such that the problem of poor electrical contact between the second electrode 9 and the auxiliary electrodes 3 due to the fact that the second electrode 9 generated later is penetrated by the particles is solved. Additionally, since the second electrode 9 has a thickness far smaller than that of the pixel defining layer 5, a mismatch gap between the second electrode 9 and the auxiliary electrode 3 is large, and poor electrical contact (false connection) between the second electrode 9 and the auxiliary electrode 3 is likely to be caused. In the present disclosure, the lap joint electrode 8′ is formed in the first through hole 52, and the lap joint electrode 8′ may remarkably reduce the mismatch gap, reduce the false connection between the second electrode 9 and the auxiliary electrode 3, and improve a yield of products.
(9) The second electrode 9 covering a whole surface on the side of the organic light emitting layer 6 away from the substrate 1 is formed. The second electrode 9 is coupled to the auxiliary electrodes 3 by means of the lap joint electrodes 8′ as shown in FIG. 4I. For example, the second electrode 9 serves as a cathode, the second electrode is made of a transparent conductive material, and the cathode may be formed from a composite material of one or more of a magnesium-silver mixture, indium zinc oxide (IZO), indium tin oxide (ITO), aluminum doped zinc oxide (AZO), etc.

According to the manufacturing method provided in the embodiments of the present disclosure, the part of the organic light emitting layer in the corresponding region is removed by laser irradiation, such that the organic light emitting layer covers part of the pixel defining layer, and an orthographic projection of the organic light emitting layer on the substrate and an orthographic projection of the auxiliary electrode on the substrate do not overlap. Then the formed second electrode is coupled to the auxiliary electrode by means of the lap joint electrodes, and the second electrode and the auxiliary electrode are equivalently connected in parallel, such that the auxiliary electrode may reduce the resistance of the second electrode, thereby reducing the IR drop. In addition, according to the embodiments of the present disclosure, when the part of the organic light emitting layer in the corresponding region is removed by laser irradiation, the mask is used to shield the region not irradiated by the laser, such that the mask may effectively isolate particles generated during laser irradiation, thereby avoiding pollution of the particles generated during laser irradiation to the organic light emitting layer, and facilitating removal of the particles. Thus, the embodiments of the present disclosure achieve reduction to the resistance of the second electrode on the basis of not polluting the organic light emitting layer.

### Embodiment 4

The embodiment of the present disclosure provides a display device, including any one of the organic light emitting display panels mentioned above.

The principle of solving a problem of the display device is similar to that of the organic light emitting display panel mentioned above, such that implementation of the display device may refer to the implementation of the organic light emitting display panel mentioned above, and the repeated description is not made herein.

In specific implementations, the display device provided in the embodiments of the disclosure may be a mobile phone, a tablet, a television, a display apparatus, a laptop, a digital photo frame, a navigator and other products or components with display functions. Other essential parts of the display device are understood by an ordinary person skilled in the art, are not described in detail herein, and should not be taken as a limitation to the present disclosure.

According to the organic light emitting display panel, the manufacturing method and the display device provided in the embodiments of the present disclosure, the part of the organic light emitting layer in the corresponding region is removed by laser irradiation, such that the organic light emitting layer covers part of the pixel defining layer, and an orthographic projection of the organic light emitting layer on the substrate and an orthographic projection of the auxiliary electrodes on the substrate do not overlap. Then the formed second electrode is coupled to the auxiliary electrode by means of the lap joint electrode, and the second electrode and the auxiliary electrode are equivalently connected in parallel, such that the auxiliary electrode may reduce the resistance of the second electrode, thereby reducing the IR drop. In addition, according to the embodiments of the present disclosure, when the part of the organic light emitting layer in the corresponding region is removed by laser irradiation, the mask is used to shield the region not irradiated by the laser, such that the mask may effectively isolate particles generated during laser irradiation, thereby avoiding pollution of the particles generated during laser irradiation to the organic light emitting layer, and facilitating removal of the particles. Thus, the embodiments of the present disclosure achieve reduction to the resistance of the second electrode on the basis of not polluting the organic light emitting layer.

Apparently, those skilled in the art may make various modifications and variations to the present disclosure without departing from the spirit and scope of the present disclosure. In this way, if these modifications and variations of the present disclosure fall within the scope of the claims of the present disclosure and their equivalent technologies, the present disclosure is also intended to include these modifications and variations.

1. An organic light emitting display panel, comprising:
a substrate with a light emitting region and a non-light emitting region;
a planarization layer on one side of the substrate;
an auxiliary electrode on the one side of the substrate same as the planarization layer and in the non-light emitting region, wherein an orthographic projection of at least part of the auxiliary electrode on the substrate and an orthographic projection of the planarization layer on the substrate do not overlap;
a first electrode on a side of the planarization layer away from the substrate;
a pixel defining layer on a side of the first electrode away from the substrate, wherein the pixel defining layer is provided with a pixel opening region from which the first electrode is exposed and a first through hole from which the auxiliary electrode is exposed;
an organic light emitting layer on the side of the first electrode away from the substrate, wherein the organic light emitting layer covers part of the pixel defining layer, and an orthographic projection of the organic light emitting layer on the substrate and an orthographic projection of the auxiliary electrode on the substrate do not overlap;
a lap joint electrode in the first through hole; and
a second electrode on a side of the organic light emitting layer away from the substrate, wherein the second electrode is of a whole-layer structure, and the second electrode is coupled to the auxiliary electrode through the lap joint electrode.

2. The organic light emitting display panel according to claim 1, wherein the planarization layer is provided with a first via hole, and the auxiliary electrode is in the first via hole.

3. The organic light emitting display panel according to claim 2, wherein in a direction perpendicular to the substrate, the first via hole penetrates through the planarization layer, and a thickness of the auxiliary electrode is same as a thickness of the planarization layer.

4. The organic light emitting display panel according to claim 3, wherein the thickness of the auxiliary electrode is 100 nm-700 nm.

5. The organic light emitting display panel according to claim 1, wherein in a direction perpendicular to the substrate, a thickness of the lap joint electrode is same as a thickness of the pixel defining layer.

6. The organic light emitting display panel according to claim 5, wherein the thickness of the pixel defining layer is 100 nm-700 nm.

7. The organic light emitting display panel according to claim 1, wherein the first electrode is a reflective electrode, material of the second electrode is a transparent conductive material, and material of the auxiliary electrode is a metal.

8. The organic light emitting display panel according to claim 7, wherein the first electrode serves as an anode, and the second electrode serves as a cathode.

9. A display device, comprising the organic light emitting display panel according to claim 1.

10. A manufacturing method for an organic light emitting display panel, comprising:
providing a substrate with a light emitting region and a non-light emitting region;
forming a planarization layer and an auxiliary electrode on a same side of the substrate, wherein the auxiliary electrode is in the non-light emitting region, and an orthographic projection of at least part of the auxiliary electrode on the substrate and an orthographic projection of the planarization layer on the substrate do not overlap;
forming a plurality of independent first electrodes on a side of the planarization layer away from the substrate;
forming a pixel defining layer on a side of the first electrodes away from the substrate, wherein the pixel defining layer is provided with pixel opening regions from which the first electrodes are exposed and a first through hole from which the auxiliary electrode is exposed;
forming an organic light emitting layer covering a whole surface on a side of the pixel defining layer away from the substrate;
shielding the organic light emitting layer with a mask, wherein the mask comprises an opening region and a shielding region, the opening region corresponds to the auxiliary electrode, and the shielding region corresponds to other regions;
irradiating the opening region with laser, and removing a part of the organic light emitting layer corresponding to the opening region, such that the organic light emitting layer covers part of the pixel defining layer, and an orthographic projection of the organic light emitting layer on the substrate and an orthographic projection of the auxiliary electrode on the substrate do not overlap;
forming a lap joint electrode film layer on a side of the mask away from the substrate, wherein a part of the lap joint electrode film layer in the shielding region of the mask is disconnected from a part of the lap joint electrode film layer in the opening region;
removing the mask, wherein a lap joint electrode is formed in the part of the lap joint electrode film layer in the opening region; and
forming a second electrode covering a whole surface on a side of the organic light emitting layer away from the substrate, wherein the second electrode is coupled to the auxiliary electrode through the lap joint electrode.

11. The manufacturing method according to claim 10, wherein said forming the planarization layer and the auxiliary electrode on the same side of the substrate comprises:
forming the planarization layer on the side of the substrate,
patterning the planarization layer to form a first via hole penetrating through the planarization layer, and
forming the auxiliary electrode in the first via hole.

12. The manufacturing method according to claim 10, wherein irradiation of the laser has a wavelength of 308-355 nm, an energy density of 10-6000 mJ/cm², a frequency of 100-3000 Hz, and time of 5-1000 ns.

13. The manufacturing method according to claim 10, wherein said forming the organic light emitting layer covering the whole surface on the side of the pixel defining layer away from the substrate comprises:
forming the organic light emitting layer covering the whole surface on the side of the pixel defining layer away from the substrate in a vacuum evaporation or ink-jet printing manner.
